(19) United States
(12) Patent Application Publication
(10) Pub. No.: US 2024/0165922 A1
(43) Pub. Date: May 23, 2024

(54) RESIN COMPOSITION, PREPREG, FILM WITH RESIN, SHEET OF METAL FOIL WITH RESIN, METAL-CLAD LAMINATE, AND PRINTED WIRING BOARD

(71) Applicant: Panasonic Intellectual Property Management Co., Ltd., Osaka (JP)

(72) Inventors: Yasunori NISHIGUCHI, Osaka (JP); Hiroharu INOUE, Osaka (JP)

(21) Appl. No.: 18/551,122

(22) PCT Filed: Feb. 15, 2022
(86) PCT No.: PCT/JP2022/006006

§ 371 Date: Sep. 18, 2023

(30) Foreign Application Priority Data
Mar. 23, 2021 (JP) 2021-048992

(51) Int. Cl. B32B 15/08; H05K 1/03

(52) U.S. Cl. CPC B32B 15/08; H05K 1/032; B32B 2457/08

(57) ABSTRACT

A resin composition contains a curable resin. A quantity of outgas emitted from a cured product of the resin composition at a temperature falling within a range from 30° C. to 550° C. when the cured product is subjected to a thermal gravimetric analysis with a temperature increased from 30° C. to 800° C. at a temperature increase rate of 90° C. per minute is less than 27% by mass with respect to an entire mass of the cured product.

### TECHNICAL FIELD

The present disclosure generally relates to a resin composition, a prepreg, a film with resin, a sheet of metal foil with resin, a metal-clad laminate, and a printed wiring board. More particularly, the present disclosure relates to a resin composition containing a curable resin, a prepreg, a film with resin, a sheet of metal foil with resin, a metal-clad laminate, and a printed wiring board.

### BACKGROUND ART

Patent Literature 1 discloses an epoxy resin composition. The epoxy resin composition contains, as essential components thereof, (a) a novolac epoxy resin, (b) a novolac phenolic resin, and (c) a crosslinked butadiene acrylonitrile elastomer.

Patent Literature 1 also discloses an epoxy resin prepreg. The epoxy resin prepreg is formed by making a varnish including the epoxy resin composition, impregnating a fibrous base member with the varnish, and drying the varnish.

In addition, Patent Literature 1 further discloses a multilayer printed wiring board. The multilayer printed wiring board is formed by using the epoxy resin prepreg as a prepreg for bonding an inner circuit board and an outer sheet of metal foil together.

A via hole is usually opened through a multilayer printed wiring board. The via hole is a hole used to make electrical connection through a multilayer printed wiring board in the thickness direction.

Currently, the via hole is opened by laser hole cutting in most cases. This is because the laser hole cutting makes it easier to open a via hole with a small diameter than drilling. Opening a via hole with such a small diameter increases the density of the multilayer printed wiring board, thus contributing to reducing the size and weight of electronic devices.

Opening a hole through the multilayer printed wiring board of Patent Literature 1 by laser hole cutting, however, increases the chances of leaving a long overhang, which is unbeneficial.

The laser hole cutting would be performed on the multilayer printed wiring board of Patent Literature 1 by, for example, direct method in the following manner. Specifically, first, an outer sheet of metal foil is irradiated with a laser beam to open a through hole through the outer sheet of metal foil. In this state, an insulating layer (i.e., a cured prepreg for use in bonding) is continuously irradiated with the laser beam to provide a non-through hole, of which the bottom surface is the inner circuit board. In that case, the inside diameter of the through hole of the outer sheet of metal foil tends to be smaller than the inside diameter of the non-through hole of the insulating layer. In such a situation, part of the outer sheet of metal foil protrudes as a sort of burr or eaves toward the center of the through hole. Such a protruding portion is called an “overhang.”

In this case, if the overhang is too long, a chemical solution for use in a subsequent desmear process would be obstructed by the overhang and prevented from reaching every corner of the hole sufficiently, which makes it difficult to remove the smear from the bottom surface of the non-through hole. In addition, this also prevents plating from being electrodeposited sufficiently uniformly and smoothly, thus increasing the chances of leaving plating voids. Consequently, this would cause a significant decline in the connection reliability of the via hole. That is why if the overhang is too long, then the process step of removing the overhang needs to be performed. However, this means an increase in man-hour, and therefore, tends to cause a decline in productivity.

### CITATION LIST

### Patent Literature

Patent Literature 1:JP H10-077392 A

### SUMMARY OF INVENTION

It is therefore an object of the present disclosure to provide a resin composition, a prepreg, a film with resin, a sheet of metal foil with resin, a metal-clad laminate, and a printed wiring board, all of which reduce the chances of leaving the overhang involved with laser hole cutting.

A resin composition according to an aspect of the present disclosure contains a curable resin. A quantity of outgas emitted from a cured product of the resin composition at a temperature falling within a range from 30° C. to 550° C. when the cured product is subjected to a thermal gravimetric analysis with a temperature increased from 30° C. to 800° C. at a temperature increase rate of 90° C. per minute is less than 27% by mass with respect to an entire mass of the cured product.

A prepreg according to another aspect of the present disclosure includes: a base member: and a resin layer including either the resin composition or a semi-cured product of the resin composition. The resin composition or the semi-cured product is impregnated into the base member.

A film with resin according to still another aspect of the present disclosure includes: a resin layer including either the resin composition or a semi-cured product of the resin composition; and a supporting film supporting the resin layer thereon.

A sheet of metal foil with resin according to yet another aspect of the present disclosure includes: a resin layer including either the resin composition or a semi-cured product of the resin composition: and a sheet of metal foil bonded to the resin layer.

A metal-clad laminate according to yet another aspect of the present disclosure includes: an insulating layer including either a cured product of the resin composition or a cured product of the prepreg: and a metal layer bonded to the insulating layer.

A printed wiring board according to yet another aspect of the present disclosure includes: an insulating layer including either a cured product of the resin composition or a cured product of the prepreg: and conductor wiring formed on the insulating layer.

### BRIEF DESCRIPTION OF DRAWINGS

FIG. 1 is a schematic cross-sectional view illustrating a prepreg according to an exemplary embodiment of the present disclosure;

FIG. 2A is a schematic cross-sectional view illustrating a film with resin (and with no protective film) according to the exemplary embodiment of the present disclosure;

FIG. 2B is a schematic cross-sectional view illustrating a film with resin (and with a protective film) according to the exemplary embodiment of the present disclosure;

FIG. 3 is a schematic cross-sectional view illustrating a sheet of metal foil with resin according to the exemplary embodiment of the present disclosure;

FIG. 4 is a schematic cross-sectional view illustrating a metal-clad laminate (double-sided metal-clad laminate) according to the exemplary embodiment of the present disclosure;

FIG. 5A is a schematic cross-sectional view illustrating a printed wiring board (without interlevel connection) according to the exemplary embodiment of the present disclosure;

FIG. 5B is a schematic cross-sectional view illustrating a printed wiring board (with interlevel connection) according to the exemplary embodiment of the present disclosure;

FIG. 6 is a graph showing a relationship between outgas and overhang in a temperature range from 30° C. to 550° C.;

FIG. 7 is a graph showing a relationship between outgas and overhang in a temperature range from 30° C. to 600° C.; and

FIG. 8 illustrates how an overhang is left by laser hole cutting.

### DESCRIPTION OF EMBODIMENTS

### 1. Overview

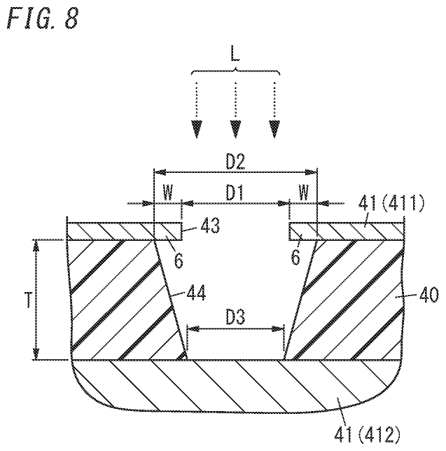

First, laser hole cutting will be described with reference to FIG. 8. An insulating layer 40 is interposed between two metal layers 41, which are arranged in the thickness direction. The two metal layers 41 are a first metal layer 411 and a second metal layer 412. That is to say, the first metal layer 411, the insulating layer 40, and the second metal layer 412 are stacked one on top of another in this order in the thickness direction. The metal layers 41 are not limited to any particular layers but may be, for example, layers containing copper. The insulating layer 40 is a layer containing a resin and having electrical insulation properties. The insulating layer 40 has a thickness T.

A through hole 43 is opened through the first metal layer 411 by irradiating the first metal layer 411 with a laser beam L in the thickness direction. In this state, the insulating layer 40 is continuously irradiated with the laser beam L to provide a non-through hole 44 in the insulating layer 40. The laser beam L is not limited to any particular laser beam but may be, for example, a CO₂ laser beam or a YAG laser beam. The laser cutting process is performed by direct method in this embodiment but may also be performed by a conformal mask method.

The through hole 43 has an inside diameter D1. The non-through hole 44 is a bottomed hole, of which the bottom surface is the surface of the second metal layer 412. The non-through hole 44 has a depth T. The non-through hole 44 is a tapered hole and has an inside diameter that decreases from the first metal layer 411 toward the second metal layer 412. The opening of the non-through hole 44 has an inside diameter (maximum inside diameter) D2. The bottom surface of the non-through hole 44 has an inside diameter (minimum inside diameter) D3. Alternatively, the non-through hole 44 may also be a straight hole. In that case, the non-through hole 44 has a constant inside diameter (i.e., D2=D3). Still alternatively, the non-through hole 44 may also be an inverted tapered hole. In that case, the inside diameter of the non-through hole 44 increases from the first metal layer 411 toward the second metal layer 412. The opening of the non-through hole 44 has an inside diameter (minimum inside diameter) D2. The bottom surface of the non-through hole 44 has an inside diameter (maximum inside diameter) D3.

In the known art, the inside diameter D1 of the through hole 43 of the first metal layer 411 tends to be smaller than the inside diameter D2 of the opening of the non-through hole 44 of the insulating layer 40. In that case, part of the first metal layer 411 protrudes as a sort of burr or eaves toward the center of the through hole 43. That part is the “overhang 6.”

The present inventors paid attention to an outgas emitted from the insulating layer 40 and involved with laser hole cutting while carrying out research to shorten the length W of the overhang 6. The present inventors carried out thermal gravimetric analysis (TGA) to measure the quantity of the outgas. As a result, the present inventors discovered that there was correlation between the quantity of the outgas and the length W of the overhang 6. Typically speaking, the present inventors discovered that the smaller the quantity of the outgas was, the shorter the overhang 6 tended to be and that the larger the quantity of the outgas was, the longer the overhang 6 tended to be. Thus, the present inventors further carried on our research to find a condition for reducing the chances of leaving the overhang 6.

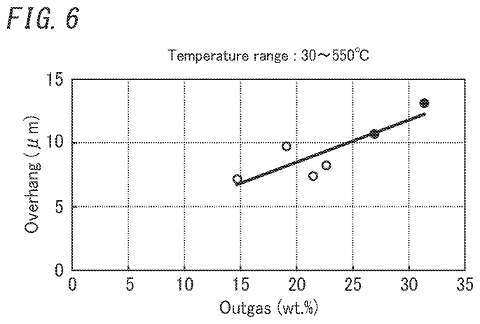

That is to say, the resin composition according to this embodiment may be used to form the insulating layer 40 as shown in FIG. 8. This resin composition contains a curable resin. The quantity of outgas emitted from a cured product of the resin composition at a temperature falling within a range from 30° C. to 550° C. when the cured product is subjected to a thermal gravimetric analysis with a temperature increased from 30° C. to 800° C. at a temperature increase rate of 90° C. per minute is less than 27% by mass with respect to the entire mass of the cured product. Thus, forming the insulating layer 40 using the resin composition according to this embodiment may reduce the chances of leaving the overhang 6, which is usually involved with laser hole cutting (refer to FIG. 6). That is to say, this allows the length W of the overhang 6 to be shortened compared to the known art.

### 2. Details

Next, a resin composition according to this embodiment will be described in detail. After that, a prepreg 1, film 2 with resin, sheet of metal foil 3 with resin, metal-clad laminate 4, and printed wiring board 5 according to this embodiment will also be described in detail with reference to the accompanying drawings.

### (1) Resin Composition

A resin composition according to this embodiment contains a curable resin. The resin composition according to this embodiment exhibits the following thermophysical properties when a cured product thereof is subjected to thermal gravimetric analysis. Specifically, the quantity of outgas emitted from a cured product of the resin composition according to this embodiment at a temperature falling within a range from 30° C. to 550° C. when the cured product is subjected to a thermal gravimetric analysis with a temperature increased from 30° C. to 800° C. at a temperature increase rate of 90° C. per minute is less than 27% by mass with respect to the entire mass of the cured product. The thermal gravimetric analysis may be carried out in, for example, a nitrogen atmosphere. The component of the outgas may be, for example, a low molecular weight component produced by decomposition of a part of the cured product.

In this case, the temperature of 550° C. is approximately equal to the temperature of the insulating layer 40 right under the first metal layer 411 when the temperature of the first metal layer 411 (e.g., copper foil, in particular) irradiated with the laser beam L reaches a melting point (e.g., a melting point of copper is about 1085° C.) during the laser hole cutting shown in FIG. 8, for example. As can be seen, setting the quantity of the outgas emitted from the cured product at a temperature falling within the range from 30° C. to 550° C. at less than 27% by mass reduces the chances of the insulating layer 40 right under the first metal layer 411 being cut off. This reduces the difference between the inside diameter D1 of the through hole 43 of the first metal layer 411 and the inside diameter D2 of the opening of the non-through hole 44 of the insulating layer 40. That is to say, this shortens the length W of the overhang 6. Consequently, this reduces the chances of leaving the overhang 6 which is usually involved with laser hole cutting.

In addition, setting the quantity of the outgas emitted from the cured product at a temperature falling within the range from 30° C. to 550° C. at less than 27% by mass also improves the flame resistance of the cured product. In general, a combustible material, oxygen, and a temperature equal to or higher than the ignition point are three essential elements for combustion. The outgas is a low molecular weight component, and therefore, may be classified as a combustible material. However, the cured product is made less easily combustible since the quantity of the outgas emitted from the cured product at a temperature falling within the range from 30° C. to 550° C. is relatively small as described above. That is to say, this may improve the flame resistance of the cured product.

It is preferable that when the thermal gravimetric analysis is carried out under the same condition as the above-described one, the quantity of the outgas emitted from the cured product at a temperature falling within the range from 30° C. to 600° C. be less than 30% by mass with respect to the entire mass of the cured product. This further reduces the chances of leaving the overhang 6.

As long as the resin composition may exhibit such thermophysical properties, the curable resin contained in the resin composition is not limited to any particular one. The curable resin is a prepolymer and may include principal agents and a curing agent. Optionally, the resin composition may further contain additional components other than the curable resin.

The curable resin preferably includes at least one compound selected from the group consisting of epoxy compounds, maleimide compounds, phenolic compounds, amide compounds, and cyanate ester compounds (cyanate compounds). This further reduces the chances of leaving the overhang 6 compared to a situation where the resin composition contains only a curable resin other than the ones enumerated above.

The epoxy compound is one of the principal agents and is a compound having at least one (preferably two or more) epoxy group(s) in a molecule. Specific examples of the epoxy compounds include, without limitation, novolac epoxy compounds, naphthol-aralkyl epoxy compounds, biphenyl-aralkyl t epoxy compounds, naphthalene epoxy resins, biphenyl epoxy resins, and dicyclopentadiene epoxy resins. Among other things, novolac epoxy compounds and biphenyl-aralkyl epoxy compounds are particularly preferred. The epoxy equivalent of the epoxy compounds is preferably equal to or greater than 150 g/eq and equal to or less than 350 g/eq.

The maleimide compound is one of the principal agents and is a compound having at least one maleimide group in a molecule. Specific examples of the maleimide compounds include, without limitation, novolac maleimide compounds (preferably phenylmethane maleimide), 4,4′-diphenylmethane bismaleimide, 3,3′-dimethyl-5,5′-diethyl-4,4′-diphenylmethane bismaleimide, and bisphenol A diphenylether bismaleimide. Adding the maleimide compound to the resin composition may cause an increase in the flame resistance of the cured product.

The phenolic compound is a type of curing agent and is a compound produced by polymerizing a phenol and formaldehyde with an acidic catalyst or a basic catalyst. Specific examples of the phenolic compound include, without limitation, novolac phenolic compounds and biphenyl-aralkyl phenolic compounds. The hydroxyl equivalent of the phenolic compound is preferably equal to or greater than 100 g/eq and equal to or less than 250 g/eq.

The amide compound is a type of curing agent and is a compound having a structure in which a dehydration-condensation reaction is caused between oxoacid and ammonia, primary amine, or secondary amine. Specific examples of the amide compound include, without limitation, dicyandiamide.

The cyanate ester compound is a type of curing agent and is a compound having at least one cyanato group in a molecule. Specific examples of the cyanate ester compound include, without limitation, novolac cyanate compounds. Adding the cyanate ester compound to the resin composition may cause an increase in the flame resistance of the cured product.

The curable resin preferably includes a biphenyl-aralkyl containing compound having a biphenyl-aralkyl structure. Specific examples of the biphenyl-aralkyl containing compounds include, without limitation, the biphenyl-aralkyl epoxy compounds and biphenyl-aralkyl phenolic compounds. This further reduces the chances of leaving the overhang 6 compared to a situation where the resin composition includes only curable resins other than the biphenyl-aralkyl containing compounds.

The proportion of the principal agents to 100 parts by mass in total of the principal agents and the curing agent is preferably equal to or greater than 60 parts by mass and equal to or less than 95 parts by mass. That is to say, the proportion of the curing agent to 100 parts by mass in total of the principal agents and the curing agent is preferably equal to or greater than 5 parts by mass and equal to or less than 40 parts by mass.

Examples of additional components other than the curable resin include, without limitation, catalysts, fillers, coupling agents (e.g., silane coupling agents), flame retardants, initiators, curing accelerators, antifoaming agents, antioxidants, polymerization inhibitors, polymerization retardants, dispersants, leveling agents, heat stabilizers, antistatic agents, ultraviolet absorbers, dyes, pigments, and lubricants.

The catalyst is a compound that promotes curing of the curable resin. Specific examples of the catalyst include, without limitation, imidazole compounds such as 2-ethyl-4-methylimidazole and metal soaps such as zinc octanoate.

The filler is an additive that improves the processability of a cured product of the resin composition or imparts functionality (such as flame retardancy). Specific examples of the fillers include silica, alumina, titanium oxide, and mica. The shape of the particles that form the filler is preferably spherical. The mean particle size of the filler is preferably equal to or greater than 0.1 μm and equal to or less than 10 μm. Note that the mean particle size herein refers to a particle size at an integrated value of 50% in a particle size distribution obtained by the laser diffraction and scattering method.

If the resin composition further contains a filler, the content (phr) of the filler is preferably equal to or greater than 50 parts by mass and equal to or less than 200 parts by mass with respect to 100 parts by mass of the curable resin.

Note that the resin composition preferably contains no elastomers except inevitably contained ones. Specific examples of the elastomers include, without limitation, acrylic rubber. This may reduce an increase in the quantity of the outgas emitted from the cured product. Nevertheless, the resin composition may contain elastomers as long as the quantity of the outgas emitted from the cured product at a temperature from 30° C. to 550° C. when the cured product is subjected to the thermal gravimetric analysis is less than 27% by mass.

### (2) Prepreg

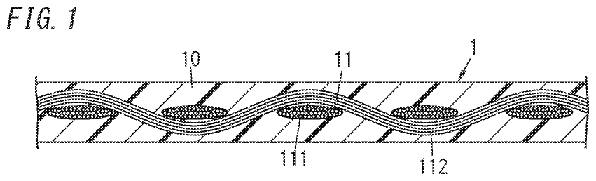

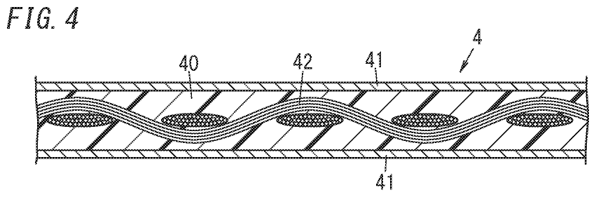

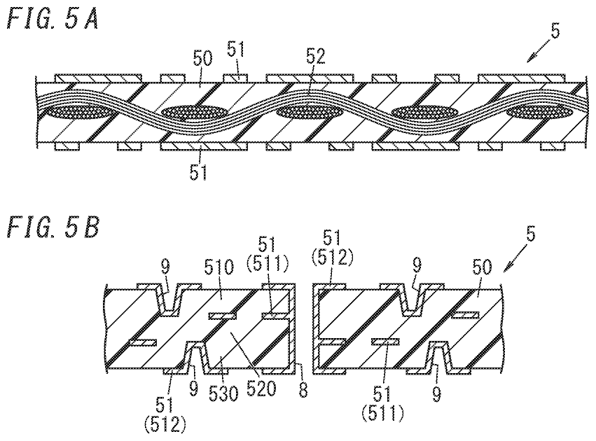

FIG. 1 illustrates a prepreg 1 according to this embodiment. The prepreg 1 has the shape of a sheet. The prepreg I may be used as a material for the metal-clad laminate 4, as a material for the printed wiring board 5, and to make a printed wiring board 5 with multiple levels (by buildup process). When heated, for example, the prepreg 1 is cured to turn into a cured product. The cured product of the prepreg I may form an insulating layer 40 of the metal-clad laminate 4 or an insulating layer 50 of the printed wiring board 5 (refer to FIG. 4 and FIGS. 5A and 5B).

The prepreg 1 includes a base member 11 and a resin layer 10. The resin layer 10 contains either a resin composition or a semi-cured product of the resin composition, each of which is impregnated into the base member 11. A sheet of the prepreg 1 includes at least one base member 11. The prepreg 1 may, but does not have to, have a thickness equal to or greater than 10 μm and equal to or less than 120 μm.

The base member 11 is a woven fabric base in which a warp 111 and a woof 112 are woven perpendicularly to each other. The base member 11 may be a woven fabric such as glass cloth. Alternatively, the base member 11 may also be a non-woven fabric such as glass non-woven fabric.

The resin layer 10 may be either a resin layer containing a resin composition (in a first case) or a resin layer containing a semi-cured product of the resin composition (in a second case).

In the first case, the resin layer 10 may be formed in the following manner. Specifically, the resin layer may be formed by impregnating a varnish of the resin composition into the base member 11 and then vaporizing the solvent. This resin layer 10 is formed as an unreacted resin composition (which is a dried product thereof). As used herein, the “unreacted state” includes a completely unreacted state and a hardly unreacted state. When heated, the resin layer 10 turns from the unreacted state into a cured state.

On the other hand, in the second case, the resin composition is in a semi-cured state. As used herein, the “semi-cured state” refers to an intermediate stage (Stage B) of a curing reaction. The intermediate stage is a stage between Stage A in the state of a varnish and Stage C in a fully cured state. In the second case, the resin layer 10 may be formed in the following manner. Specifically, the resin layer 10 may be formed by impregnating the base member 11 with a varnish of the resin composition, heating the base member 11 to vaporize the solvent, and advancing the curing reaction of the resin composition to the intermediate stage. This resin layer 10 is made of the resin composition in the semi-cured state (i.e., a semi-cured product of the resin composition).

As can be seen from the foregoing description, the degree of advancement of the curing reaction of the resin layer 10 varies according to the resin composition to use.

As can be seen, the resin layer 10 of the prepreg 1 according to this embodiment is made of the resin composition described above. Thus, using the resin layer 10 to form the insulating layer 40 shown in FIG. 8 reduces the chances of leaving the overhang 6, which is often involved with laser hole cutting.

### (3) Film with Resin

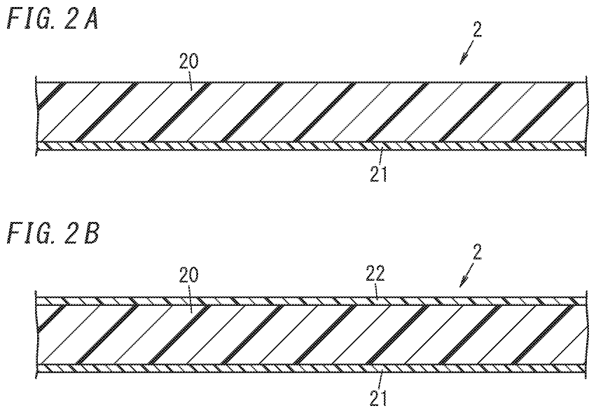

FIG. 2A illustrates a film 2 with resin according to this embodiment. The film 2 with resin has the shape of a sheet. The film 2 with resin includes a resin layer 20 and a supporting film 21. The resin layer 20 includes either a resin composition or a semi-cured product of the resin composition. The supporting film 21 supports the resin layer 20 thereon. The film 2 with resin may be used to form a printed wiring board 5 with multiple levels (by a buildup process).

When heated, for example, the resin layer 20 may turn into a cured product to form an insulating layer 40 for the metal-clad laminate 4 and an insulating layer 50 for the printed wiring board 5 (refer to FIG. 4 and FIGS. 5A and 5B). The resin layer 20 is the same as the resin layer 10 of the prepreg 1 except that the resin layer 20 is not impregnated into the base member 11. The thickness of the resin layer 20 is not limited to any particular value but may be, for example, equal to or greater than 10 μm and equal to or less than 120 μm.

The supporting film 21 supports the resin layer 20 thereon. Supporting the resin layer 20 in this way allows the resin layer 20 to be handled more easily. The supporting film 21 may be peeled off from the resin layer 20 as needed. After the resin layer 20 has been cured to form the insulating layer 40, the supporting film 21 is preferably peeled off from the insulating layer 40. The same statement applies to a situation where the insulating layer 50 is formed out of the resin layer 20.

The supporting film 21 may be, but does not have to be, an electrically insulating film, for example. Specific examples of the supporting film 21 include a polyethylene terephthalate (PET) film, a polyimide film, a polyester film, a polyparabanic acid film, a polyether ether ketone film, a polyphenylene sulfide film, an aramid film, a polycarbonate film, and a polyarylate film. However, these are only examples and the supporting film 21 does not have to be one of these films.

Although one surface of the resin layer 20 is covered with the supporting film 21 in the example shown in FIG. 2A, the other surface of the resin layer 20 may be covered with a protective film 22 with the one surface of the resin layer 20 covered with the supporting film 21 as shown in FIG. 2B. The protective film 22, as well as the supporting film 21, may also be peeled off from the resin layer 20 as needed. Covering both surfaces of the resin layer 20 in this manner allows the resin layer 20 to be handled even more easily. This also reduces the chances of foreign particles adhering onto the resin layer 20.

The protective film 22 may be, but does not have to be, an electrically insulating film, for example. Specific examples of the protective film 22 include a polyethylene terephthalate (PET) film, a polyolefin film, a polyester film, and a polymethylpentene film. However, these are only examples and the protective film 22 does not have to be one of these films.

As can be seen, the resin layer 20 of the film 2 with resin according to this embodiment is made of the resin composition described above. Therefore, using the resin layer 20 to form the insulating layer 40 shown in FIG. 8 may reduce the chances of leaving the overhang 6, which is often involved with laser hole cutting.

### (4) Sheet of Metal Foil with Resin

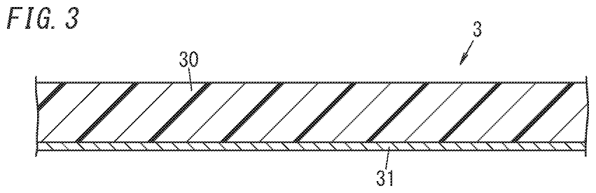

FIG. 3 illustrates a sheet of metal foil 3 with resin according to this embodiment. The sheet of metal foil 3 with resin has the shape of a sheet. The sheet of metal foil 3 with resin includes a resin layer 30 and a sheet of metal foil 31. The resin layer 30 contains either the resin composition or a semi-cured product of the resin composition. The sheet of metal foil 31 is bonded to the resin layer 30. The sheet of metal foil 3 with resin may be used, for example, to form a printed wiring board 5 with multiple levels (by buildup process).

When heated, for example, the resin layer 30 may turn into a cured product to form the insulating layer 40 of the metal-clad laminate 4 and the insulating layer 50 of the printed wiring board (refer to FIG. 4 and FIGS. 5A and 5B). The resin layer 30 is the same as the resin layer 10 of the prepreg 1 except that the resin layer 30 is not impregnated into the base member 11. The thickness of the resin layer 30 is not limited to any particular value but may be, for example, equal to or greater than 10 μm and equal to or less than 120 μm.

The sheet of metal foil 31 may be, but does not have to be, a sheet of copper foil, a sheet of aluminum foil, or a sheet of nickel foil. The sheet of metal foil 31 may be patterned into conductor wiring 51 by having unnecessary portions thereof etched away by subtractive process, for example (refer to FIGS. 5A and 5B). The thickness of the sheet of metal foil 31 is not limited to any particular value but is preferably equal to or greater than 1 μm and equal to or less than 18 μm.

If the sheet of metal foil 31 is configured as an extremely thin sheet of metal foil, then the sheet of metal foil 31 preferably forms part of an extremely thin sheet of metal foil with carrier foil from the viewpoint of improving its handleability. The extremely thin sheet of metal foil with the carrier foil includes the sheet of metal foil 31 (extremely thin sheet of metal foil), a peelable layer, and carrier foil. In that case, the sheet of metal foil 31 has a thickness equal to or less than 3 μm, for example. The peelable layer is used to temporarily bond the sheet of metal foil 31 to the carrier foil. The sheet of metal foil 31 is peeled off as needed from either the peelable layer or the carrier foil. The carrier foil is a support for supporting the sheet of metal foil 31 thereon. Specific examples of the carrier foil include a sheet of copper foil and a sheet of aluminum foil. The carrier foil is thicker than the sheet of metal foil 31.

As can be seen, the resin layer 30 of the sheet of metal foil 3 with resin according to this embodiment is made of the resin composition described above. Therefore, using the resin layer 30 to form the insulating layer 40 shown in FIG. 8 may reduce the chances of leaving the overhang 6, which is often involved with laser hole cutting.

### (5) Metal-Clad Laminate

FIG. 4 illustrates a metal-clad laminate 4 according to this embodiment. The metal-clad laminate 4 includes an insulating layer 40 and at least one metal layer 41. The metal-clad laminate 4 may be used, for example, as a material for the printed wiring board 5.

The insulating layer 40 includes either a cured product of the resin composition or a cured product of the prepreg 1. Although the single insulating layer 40 includes a single base member 42 in the example illustrated in FIG. 4, the single insulating layer 40 may include two or more base members 42. The thickness of the insulating layer 40 is not limited to any particular value but may be, for example, equal to or greater than 10 μm and equal to or less than 120 μm.

The metal layer(s) 41 is/are bonded to the insulating layer 40. Although the metal layers 41 are respectively bonded to both surfaces of the insulating layer 40 in the example illustrated in FIG. 4, the metal layer 41 may be bonded to only one surface of the insulating layer 40. The metal-clad laminate 4 having the metal layers 41 respectively bonded to both surfaces of the insulating layer 40 is a double-sided metal-clad laminate. The metal-clad laminate 4 having the metal layer 41 bonded to only surface of the insulating layer 40 is a single-sided metal-clad laminate.

The metal layer 41 may be, but does not have to be, a sheet of metal foil, for example. The sheet of metal foil may be, but does not have to be, a sheet of copper foil, a sheet of aluminum foil, or a sheet of nickel foil, for example.

The thickness of the metal layer 41 is not limited to any particular value but may be, for example, equal to or greater than 1 μm and equal to or less than 18 μm. If the metal layer 41 is an extremely thin sheet of metal foil, then the metal layer 41 preferably forms part of an extremely thin sheet of metal foil with carrier foil from the viewpoint of improving its handleability. The extremely thin sheet of metal foil with carrier foil is as described above.

As can be seen, the insulating layer 40 of the metal-clad laminate 4 according to this embodiment includes either a cured product of the resin composition or a cured product of the prepreg 1. Therefore, using the insulating layer 40 may reduce the chances of leaving the overhang 6, which is often involved with laser hole cutting.

### (6) Printed Wiring Board

FIGS. 5A and 5B illustrate printed wiring boards 5 according to this embodiment. Each of the printed wiring boards 5 includes an insulating layer 50 and conductor wiring 51.

The insulating layer 50 includes either a cured product of the resin composition or a cured product of the prepreg 1. The printed wiring board 5 shown in FIG. 5A includes a single insulating layer 50. In FIG. 5A, the single insulating layer 50 includes a single base member 52. However, this is only an example and should not be construed as limiting. Alternatively, the single insulating layer 50 may include two or more base members 52.

On the other hand, the printed wiring board 5 shown in FIG. 5B includes a plurality of (specifically, three) insulating layers 50, namely, a first insulating layer 510, a second insulating layer 520, and a third insulating layer 530. These three insulating layers 50 are stacked one on top of another in this order in the thickness direction and are bonded to each other. In FIG. 5B, each of the first insulating layer 510, the second insulating layer 520 and the third insulating layer 530 may include no base member 52 or include one or more base members 52. As can be seen, the insulating layer 50 is the same as the insulating layer 40 of the metal-clad laminate 4 described above.

The conductor wiring 51 is formed on the insulating layer 50. In the printed wiring board 5 shown in FIG. 5A, the conductor wiring 51 is formed on each of the two surfaces of the insulating layer 50. Alternatively, the conductor wiring 51 may be formed on only one surface of the insulating layer 50.

On the other hand, in the printed wiring board shown in FIG. 5B, the conductor wiring 51 includes an internal circuit 511 and an external circuit 512. The internal circuit 511 is located between two insulating layers 50. Specifically, the internal circuit 511 is located between the first insulating layer 510 and the second insulating layer 520 and between the second insulating layer 520 and the third insulating layer 530. The external circuit 512 is located outside of the insulating layer 50. That is to say, the external circuit 512 is formed on the surface of the first insulating layer 510 and on the surface of the third insulating layer 530. The printed wiring board 5 shown in FIG. 5B further includes a plated through hole 8 and blind via holes 9. The plated through hole 8 and the blind via holes 9 electrically connect the internal circuit 511 and the external circuit 512 to each other. That is to say, the internal circuit 511 and the external circuit 512 are interconnected via the plated through hole 8 and the blind via holes 9.

The conductor wiring 51 may be, but does not have to be, formed by, for example, subtractive process, semi-additive process (SAP), or modified semi-additive process (MSAP).

As can be seen, the insulating layer 50 of the printed wiring board 5 according to this embodiment includes either a cured product of the resin composition or a cured product of the prepreg 1. Therefore, using the insulating layer 50 may reduce the chances of leaving the overhang 6, which is often involved with laser hole cutting.

### (7) Laser Hole Cutting Method

Next, it will be described with reference to FIG. 8 how to make laser hole cutting using the resin composition according to this embodiment.

The laser beam L to use may be, but does not have to be, a CO₂ laser beam or a YAG laser beam, for example. The wavelength of the CO₂ laser beam may be, without limitation, equal to or greater than 9 μm and equal to or less than 11 μm, for example.

Examples of the laser cutting method include, without limitation, a direct method and a conformal mask method. In this embodiment, the direct method is preferably adopted. The direct method is a method for opening a hole through the first metal layer 411 and the insulating layer 40 directly with the laser beam L without providing an opening (i.e., the through hole 43) through the first metal layer 411 in advance by chemical etching, for example. The direct method makes it easier than the conformal mask method to open a hole with a small diameter, improve the positional accuracy of the hole, and control the shape of the hole. In addition, the direct method also eliminates the need to perform a window etching process, which is indispensable for the conformal mask process, thus simplifying the process to the point of significantly cutting down the cost advantageously.

The insulating layer 40 contains a cured product of the resin composition according to this embodiment and has electrical insulation properties. That is to say, examples of the insulating layer 40 include the insulating layer 40 of the metal-clad laminate 4 and the insulating layer 50 of the printed wiring board 5 described above. The thickness T of the insulating layer 40 is preferably equal to or greater than 10 μm and equal to or less than 120 μm.

The metal layer 41 may be, but does not have to be, a layer containing copper, for example. Examples of the layers containing copper include, without limitation, a sheet of copper foil. The first metal layer 411 is preferably thick enough to open the through hole 43 directly with the laser beam L. The thickness of the first metal layer 411 may be, for example, equal to or greater than 1 μm and equal to or less than 18 μm. On the other hand, the thickness of the second metal layer 412 is not limited to any particular value.

It is preferable that the first metal layer 411 be subjected to surface treatment. The surface treatment may be, without limitation, blackening treatment and roughening treatment using a sulfuric acid-hydrogen peroxide-based chemical solution. This allows the first metal layer 411 to have a higher absorptivity to the laser beam L.

Then, the first metal layer 411 is irradiated with the laser beam L in the thickness direction to open the through hole 43 through the first metal layer 411. In this state, the insulating layer 40 is continuously irradiated with the laser beam L to open the non-through hole 44 through the insulating layer 40. In this case, the laser beam L preferably has a pulse width equal to or greater than 10 usec and equal to or less than 14 usec. The energy of the laser beam Lis preferably equal to or greater than 3 mJ and equal to or less than 6 mJ.

The insulating layer 40 includes a cured product of the resin composition according to this embodiment, and therefore, may reduce the chances of leaving the overhang 6 which is usually involved with the laser hole cutting. The through hole 43 penetrating through the first metal layer 411 may have an inside diameter D1 equal to or greater than 50 μm and equal to or less than 60 μm, for example. The opening of the non-through hole 44 may have an inside diameter D2 equal to or greater than 55 μm and equal to or less than 80 μm. The aspect ratio (T/D2) is equal to or greater than 0.5 and equal to or less than 1. The length W of the overhang 6 may be less than 11 μm. Thus, the overhang 6 may have a shorter length W than the known ones.

Shortening the length W of the overhang 6 in this manner allows the chemical solution to reach even the depth of the non-through hole 44 sufficiently during a subsequent desmear process, thus making it easier to remove the smear from inside the non-through hole 44. Therefore, this allows plating to be electrodeposited on the inner surface of the non-through hole 44 sufficiently uniformly, thus improving the connection reliability of the via hole. In addition, shortening the overhang 6 eliminates the need to perform the process step of removing the overhang 6, which would cause a significant increase in productivity as well.

### EXAMPLES

Next, specific examples of the present disclosure will be described. Note that the examples to be described below are only examples of the present disclosure and should not be construed as limiting.

### (1) Resin Composition

The following are materials for the resin composition:

### <Curable Resin>

### <<Principal Agents>>

### [Epoxy Compound]

Novolac epoxy compound, product name “EPPN-201,” manufactured by Nippon Kayaku Co., Ltd. and having an epoxy equivalent of 180 to 200 g/eq;
Naphthol-aralkyl epoxy compound, product name “HP-9500,” manufactured by DIC Corporation and having an epoxy equivalent of 200 to 240 g/eq; and
Biphenyl-aralkyl epoxy compound, product name “NC-3000-H,” manufactured by Nippon Kayaku Co., Ltd. and having an epoxy equivalent of 280 to 300 g/eq.

### [Maleimide Compound]

Novolac maleimide compound, product name “BMI-2300,” manufactured by Daiwa Fine Chemicals Co., Ltd., phenylmethane maleimide.

### <<Curing Agent>>

### [Amide Compound]

Dicyandiamide (DICY) manufactured by Nippon Carbide Industries Co., Inc.

### [Phenolic Compound]

Novolac phenolic compound, product name “TD-2090-60M,” manufactured by DIC Corporation and having a hydroxyl equivalent of 105 g/eq; and
Biphenyl-aralkyl phenolic compound, product name “GPH-103,” manufactured by Nippon Kayaku Co., Ltd. and having a hydroxyl equivalent of 220 to 240 g/eq.

### [Cyanate Compound]

Novolac cyanate compound, product name “PT-30” manufactured by Lonza.

### <Others>

### <<Elastomer>>

Acrylic rubber (acrylic acid ester-based polymer), product name “SG-P3,” manufactured by
Nagase ChemteX Corporation and having a weight average molecular weight of 850000.

### <<Catalyst>>

2-ethyl-4-methylimidazole, product name “2E4MZ,” manufactured by Shikoku Chemicals Corporation; and
Zinc octanoate, product name “Zn-OCTOATE 20% T,” manufactured by DIC Corporation, metal species: Zn, and having a metal content of 20%.

### <<Filler>>

Spherical silica, product name “SC2050-MB,” manufactured by Admatechs, and having a mean particle size of 0.5 μm.

The curable resin and the other components were compounded together to have any of the compositions shown in the following Table 1 and mixed with an appropriate solvent. The mixture was stirred up to be homogenized. In this manner, a varnish of the resin composition was prepared.

### (2) Sheet of Metal Foil with Resin

The varnish thus prepared was applied onto an extremely thin sheet of metal foil with carrier foil (extremely thin sheet of copper foil with carrier foil, product name “MT18FL,” manufactured by Mitsui Mining & Smelting Co., Ltd., thickness of the extremely thin sheet of copper foil: 1.5 μm, and thickness of the carrier foil: 18 μm) and then heated and dried at a temperature of 90° C. to 140° C. for about 4 minutes, thereby making a sheet of metal foil with resin (sheet of copper foil with resin) with a resin layer having a thickness of approximately 50 μm.

### (3) Metal-clad Laminate

### (3.1) First Board for Evaluation

Two sheets of such metal foil with resin were stacked one on top of the other such that their resin layers faced each other. Then, the stack was subjected to vacuum molding under the condition including a temperature of 220° C. , a pressure of 2 MPa, and a duration of two hours. In this manner, a double-sided metal-clad laminate (double-sided copper-clad laminate) with an insulating layer having a thickness of approximately 0.1 mm was manufactured. The board thus manufactured was regarded as a first board for evaluation.

### (3.2) Second Board for Evaluation

The sheet of metal foil with resin was stacked on each of the two sides of the double-sided metal-clad laminate (double-sided copper-clad laminate) with an insulating layer having a thickness of 0.2 mm such that their resin layers faced each other. Then, the assembly was subjected to vacuum molding under the same condition as the first board for evaluation described above. In this manner, a quadruple-layer board was manufactured and regarded as a second board for evaluation.

### (4) Physical Properties

The insulating layer of the first board for evaluation was subjected to a thermal gravimetric analysis with the temperature increased from 30° C. to 800° C. at a temperature increase rate of 90° C. per minute. The quantities of outgas emitted from the insulating layer were measured in a temperature range from 30° C. to 550° C. and in a temperature range from 30° C. to 600° C. The results are summarized in the following Table 1.

### (5) Tests

### (5.1) Overhang

Using a laser cutting machine for opening a hole through a board (model number “ML605GTW4-P” manufactured by Mitsubishi Electric Corporation), the second board for evaluation was subjected to laser hole cutting by the direct method using a CO₂ laser beam. In this manner, a through hole penetrating through the surface sheet of copper foil and having an inside diameter (corresponding to D1 shown in FIG. 8) of 50 μm and a non-through hole having a depth (corresponding to T shown in FIG. 8) of 50 μm were opened. The laser hole cutting was carried out under the following condition:
Mask: φ1.4 mm;
Pulse width: 12 usec; and
Energy: 4.0-5.0 mJ.

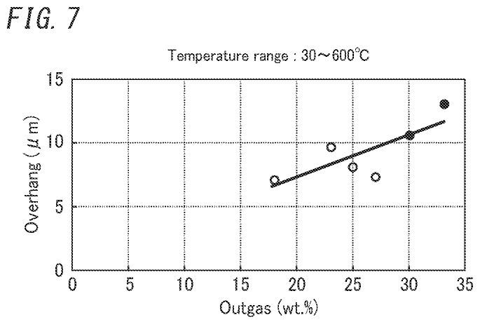

With respect to this non-through hole, the length of the overhang was measured. The results are summarized in the following Table 1. In addition, data representing the correlation between the quantity of the outgas and the length of the overhang were plotted to make a graph. FIG. 6 is a graph showing the correlation between the quantity of the outgas emitted and the length of the overhang left in a temperature range from 30° C. to 550° C. FIG. 7 is a graph showing the correlation between the quantity of the outgas emitted and the length of the overhang left in a temperature range from 30° C. to 600° C. In FIGS. 6 and 7, the results of specific examples of the present disclosure are indicated by open circles and the results of comparative examples are indicated by solid circles. A line fitting these data is drawn by the least squares method.

### (5.2) Flame Resistance

Test pieces, each having a length of 125 mm and a width of 12.5 mm, were cut out of the first board for evaluation. The test pieces were subjected to flammability tests (vertical flame tests) ten times in accordance with “Test for Flammability of Plastic Materials—UL 94” by Underwriters Laboratories. Specifically, each of five test pieces was subjected to the flammability test twice apiece. The average duration for which the test piece continued to burn during the flammability tests was obtained. The test piece was graded as follows by its flame resistance:
“V-0”: if the average duration was equal to or shorter than 5 seconds;
“V-1”: if the average duration was longer than 5 seconds; and
“V-2”: if the test piece continued to burn to the end.

TABLE 1

| | | | | | Examples | | | | Comparative Examples | | |
|---|---|---|---|---|---|---|---|---|---|---|---|
| | | | | Unit | 1 | 2 | 3 | 4 | 1 | 2 | 3 |
| Curable | Principal | Epoxy compound | Novolac | Parts by mass | 95 | 0 | 0 | 0 | 60 | 0 | 60 |
| Resin | Agents | | Naphthol-aralkyl | Parts by mass | 0 | 0 | 0 | 0 | 0 | 70 | 0 |
| | | | Biphenyl-aralkyl | Parts by mass | 0 | 60 | 0 | 0 | 0 | 0 | 0 |
| | | Maleimide compound | Novolac | Parts by mass | 0 | 0 | 60 | 60 | 0 | 0 | 0 |
| | Curing | Amide compound | DICY | Parts by mass | 5 | 0 | 0 | 0 | 0 | 0 | 0 |
| | Agent | Phenolic compound | Novolac | Parts by mass | 0 | 0 | 40 | 0 | 40 | 30 | 40 |
| | | | Biphenyl-aralkyl | Parts by mass | 0 | 40 | 0 | 0 | 0 | 0 | 0 |
| | | Cyanate compound | Novolac | Parts by mass | 0 | 0 | 0 | 40 | 0 | 0 | 0 |

| | | | | | | | | | | |
|---|---|---|---|---|---|---|---|---|---|---|
| Others | Elastomer | Acrylic rubber | phr | 0 | 0 | 0 | 0 | 0 | 0 | 30 |
| | Catalyst | Imidazole | phr | 1 | 1 | 1 | 0 | 1 | 1 | 1 |
| | | Zinc octanoate | phr | 0 | 0 | 0 | 0.05 | 0 | 0 | 0 |
| | Filler | Spherical silica | phr | 100 | 100 | 100 | 100 | 100 | 100 | 100 |
| Physical | Quantity of | Temperature range: 30° C.-550° C. | wt % | 23 | 21 | 19 | 15 | 27 | 31 | 37 |
| Properties | Outgas | Temperature range: 30° C.-600° C. | wt % | 25 | 27 | 23 | 18 | 30 | 33 | 42 |

| | | | | | | | | | |
|---|---|---|---|---|---|---|---|---|---|
| Evaluation | Overhang | μm | 8 | 7 | 10 | 7 | 11 | 13 | 13 |
| | Flammability (UL 94) | — | — | V-1 | V-2 | V-0 | — | — | — |

1. A resin composition containing a curable resin,
a quantity of outgas emitted from a cured product of the resin composition at a temperature falling within a range from 30° C. to 550° C. when the cured product is subjected to a thermal gravimetric analysis with a temperature increased from 30° C. to 800° C. at a temperature increase rate of 90° C. per minute being less than 27% by mass with respect to an entire mass of the cured product.

2. The resin composition of claim 1, wherein
a quantity of the outgas emitted from the cured product at a temperature falling within a range from 30° C. to 600° C. is less than 30% by mass with respect to the entire mass of the cured product.

3. The resin composition of claim 1, wherein
the curable resin includes at least one compound selected from the group consisting of epoxy compounds, maleimide compounds, phenolic compounds, amide compounds, and cyanate ester compounds.

4. The resin composition of claim 1, wherein
the curable resin includes a biphenyl-aralkyl-containing compound having a biphenyl-aralkyl structure.

5. A prepreg comprising: a base member: and a resin layer including either the resin composition of claim 1 or a semi-cured product of the resin composition, the resin composition or the semi-cured product being impregnated into the base member.

6. A film with resin comprising: a resin layer including either the resin composition of claim 1 or a semi-cured product of the resin composition; and a supporting film supporting the resin layer thereon.

7. A sheet of metal foil with resin, comprising: a resin layer including either the resin composition of claim 1 or a semi-cured product of the resin composition; and a sheet of metal foil bonded to the resin layer.

8. A metal-clad laminate comprising: an insulating layer including a cured product of the resin composition of claim 1; and a metal layer bonded to the insulating layer.

9. A printed wiring board comprising: an insulating layer including a cured product of the resin composition of claim 1; and conductor wiring formed on the insulating layer.

10. The resin composition of claim 2, wherein
the curable resin includes at least one compound selected from the group consisting of epoxy compounds, maleimide compounds, phenolic compounds, amide compounds, and cyanate ester compounds.

11. The resin composition of claim 2, wherein
the curable resin includes a biphenyl-aralkyl-containing compound having a biphenyl-aralkyl structure.

12. The resin composition of claim 3, wherein
the curable resin includes a biphenyl-aralkyl-containing compound having a biphenyl-aralkyl structure.

13. A metal-clad laminate comprising: an insulating layer including a cured product of the prepreg of claim 5; and a metal layer bonded to the insulating layer.

14. A printed wiring board comprising: an insulating layer including a cured product of the prepreg of claim 5; and conductor wiring formed on the insulating layer.
